(19) United States
(12) Patent Application Publication
(10) Pub. No.: US 2024/0402588 A1
(43) Pub. Date: Dec. 5, 2024

(54) METHOD FOR FABRICATING MASK, AND METHOD FOR MANUFACTURING SEMICONDUCTOR DEVICE USING THE SAME

(71) Applicant: SAMSUNG ELECTRONICS CO., LTD., SUWON-SI (KR)

(72) Inventors: Young-Ah KIM, SUWON-SI (KR); Byung Jun KANG, SUWON-SI (KR); Bong Keun KIM, SUWON-SI (KR); Joong Un PARK, SUWON-SI (KR); Hyung Joo YOUN, SUWON-SI (KR); Jae Young CHOI, SUWON-SI (KR)

(21) Appl. No.: 18/615,901

(22) Filed: Mar. 25, 2024

(30) Foreign Application Priority Data
Jun. 2, 2023 (KR) 10-2023-0071893

(51) Int. Cl. G03F 1/36; H01L 21/027; H01L 29/423; H01L 29/66

(52) U.S. Cl. CPC G03F 1/36; H01L 21/027; H01L 29/42392; H01L 29/66439

(57) ABSTRACT

A method for fabricating mask is provided. The method includes generating a second target pattern from a first target pattern, where the first target pattern includes first straight edges, and the second target pattern includes second straight edges and curved edges. Optical proximity correction is performed on the second target pattern to generating a mask pattern. The mask is fabricated using the mask pattern. Generating the second target pattern includes changing corner portions of the first target pattern into a curve to generate the curved edges.

### CROSS-REFERENCE TO RELATED APPLICATION

This application claims priority under 35 U.S.C. § 119 to Korean Patent Application No. 10-2023-0071893, filed on Jun. 2, 2023 in the Korean Intellectual Property Office, the contents of which are herein incorporated by reference in its entirety.

### TECHNICAL FIELD

The present disclosure relates to semiconductor masks and, more specifically, to a method for fabricating a mask, and a method for manufacturing a semiconductor device using the same.

### DISCUSSION OF THE RELATED ART

Generally, semiconductor chips are patterned by the use of a photolithography process that exposes the semiconductor through a mask and then an etch process is used to either remove or keep only the exposed pattern. Before this, however, a chip layout is designed and this layout is used to create the mask. When a circuit pattern on a mask is transferred onto the wafer in a photolithography process to form a circuit pattern (hereinafter, a “transferred circuit pattern”) on the wafer, a difference is generated between the transferred circuit pattern on the wafer and an actual design circuit pattern. This is to say that the patterned chips might not be identical to the designed mask layout. This difference is due to an optical proximity effect in the photolithography process or a loading effect in the etch process. A scheme for accurately transferring the circuit pattern on the mask onto the wafer employs a process proximity correction (PPC) technique to correct the circuit pattern in consideration of deformation of the transferred circuit pattern on the wafer. The process proximity correction scheme predicts and pre-analyzes the optical proximity effect and the loading effect, and corrects a layout of the circuit pattern on the mask based on the analysis result. An optical proximity correction scheme in the photolithography process is mainly used as the process proximity correction scheme.

### SUMMARY

A method for fabricating a mask includes generating a second target pattern from a first target pattern. The first target pattern includes first straight edges. The second target pattern includes second straight edges and curved edges. Optical proximity correction is performed on the second target pattern to generating a mask pattern. The mask is fabricated using the mask pattern. Generating the second target pattern includes changing corner portions of the first target pattern into a curve to generate the curved edges.

A method for fabricating a mask includes generating a target pattern composed of straight edges and curved edges. Optical proximity correction is performed on the target pattern to generate a mask pattern. The mask is fabricated using the mask pattern. The performing of the optical proximity correction on the target pattern includes generating first mask control points on each of the straight edges of the target pattern and generating second mask control points on each of the curved edges of the target pattern. A density of the first mask control points is different from a density of the second mask control points.

A method for manufacturing a semiconductor device includes fabricating a mask and performing a photolithographic process on a substrate using the mask. Fabricating the mask includes generating a second target pattern from a first target pattern. Optical proximity correction is performed on the second target pattern to generating a mask pattern. The mask is fabricated using the mask pattern. The first target pattern includes a first straight edge and a second straight edge extending in a horizontal direction and a step edge connecting the first straight edge and the second straight edge to each other. Generating the second target pattern includes changing the step edge of the first target pattern to a curve to generate a curved edge.

### BRIEF DESCRIPTION OF DRAWINGS

The above and other aspects and features of the present disclosure will become more apparent by describing in detail illustrative embodiments thereof with reference to the attached drawings, in which:

FIG. 1 is a flow chart illustrating a method for fabricating a mask according to some embodiments;

FIG. 2 to FIG. 12 are diagrams illustrating a method for fabricating a mask according to some embodiments;

FIG. 13 and FIG. 14 are diagrams illustrating a method for fabricating a mask according to some embodiments;

FIG. 15 and FIG. 16 are diagrams illustrating a method for fabricating a mask according to some embodiments;

FIG. 17 is a block diagram showing a mask fabricating device according to some embodiments;

FIG. 18 is a flow chart illustrating a method for manufacturing a semiconductor device in accordance with some embodiments;

FIG. 19 is a block diagram illustrating a photolithography system for performing a method for manufacturing a semiconductor device according to some embodiments;

FIG. 20 is a diagram showing an example of a photomask included in the photolithography system of FIG. 19;

FIG. 21 is a diagram showing printing of a circuit pattern on a substrate using the photomask of FIG. 20; and

FIG. 22 to FIG. 24 are diagrams illustrating a semiconductor device according to some embodiments.

### DETAILED DESCRIPTIONS

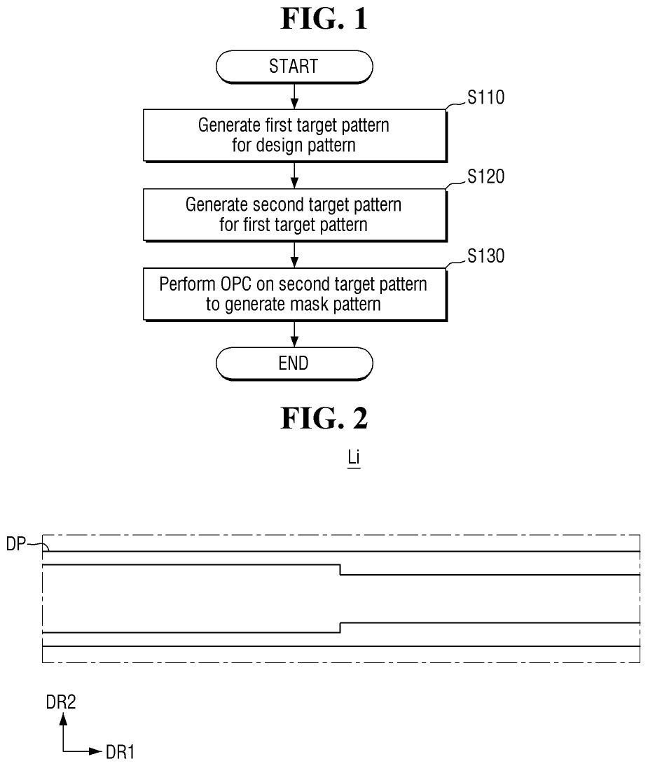

FIG. 1 is a flow chart illustrating a method for fabricating a mask according to some embodiments. FIG. 2 to FIG. 12 are diagrams illustrating a method for fabricating a mask according to some embodiments.

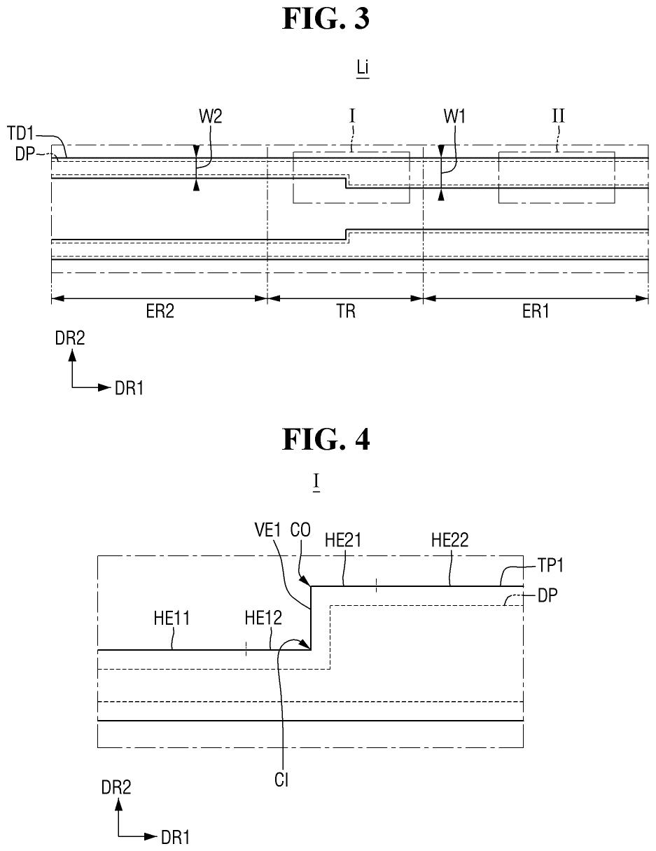

Referring to FIG. 1 and FIG. 3, a first target pattern TP1 is generated from a design pattern DP in S110.

An initial layout Li includes the design pattern DP. For example, the design pattern DP may have a step shape or an L shape. For example, the design pattern DP may include a first portion having a first width in a vertical direction DR2 and a second portion having a second width in the vertical direction DR2 that is smaller than the first width and thus may have a step portion.

The design pattern DP includes straight edges. In following descriptions, the straight edge refers to a vertical edge extending in the vertical direction DR2 or a horizontal edge extending in a horizontal direction DR1.

The design pattern DP includes horizontal edges extending in the horizontal direction DR1 and vertical edges extending in the vertical direction DR2. The design pattern DP includes a corner defined by the horizontal edge and the vertical edge.

The first target pattern TP1 may be generated from the design pattern DP in a TDLO (Table Driven Layout Operation) procedure. The first target pattern TP1 may define a size of a pattern (for example, a photoresist pattern) to be developed from a photoresist in the photolithography process. For example, the first target pattern TP1 may mean a target size of the photoresist pattern to be actually developed.

The design pattern DP may mean a size of a final pattern to be formed in an etch target layer under the photoresist. The final pattern formed on the etch target layer may be formed to have a smaller size than a size of the photoresist pattern formed in the photolithography process. This is because an etch profile is inclined while patterning the etch target layer using the photoresist pattern as an etch mask. In summary, generating the first target pattern TP1 in S110 is a process of correcting a difference between the size of the pattern developed from the photoresist and the size of the pattern formed in the etch target layer.

The first target pattern TP1 has a different size from that of the design pattern DP, but may have a similar shape to a shape of the design pattern DP. For example, the first target pattern TP1 may have a step shape or an L shape.

The first target pattern TP1 includes an extension extending in the horizontal direction DR1 and/or the vertical direction DR2 and a transition including a corner portion.

The first target pattern TP1 may include a first extension ER1, a second extension ER2, and a transition TR. The first extension ER1, the second extension ER2, and transition TR may be sequentially connected to each other. The transition TR may connect the first extension ER1 and the second extension ER2 to each other. The first extension ER1 and the second extension ER2 may extend along the horizontal direction DR1. The first extension ER1 may have a first width W1 in the vertical direction DR2. The second extension ER2 may have a second width W2 in the vertical direction DR2. Each of the first extension ER1 and the second extension ER2 may have a line shape extending in the horizontal direction DR1.

The second width W2 may be smaller than the first width W1. The transition TR may include a portion connected to the first extension ER1 and having the first width W1, and a portion connected to the second extension ER2 and having the second width W2. The transition TR may have a step shape.

Referring to FIG. 1 and FIG. 4, the transition TR includes a first horizontal edge HE11 and HE12, a second horizontal edge HE21 and HE22, and a first vertical edge VE1. The first vertical edge VE1 is connected to the first horizontal edge HE11 and HE12 and the second horizontal edge HE21 and HE22. For example, the first horizontal edge HE11 and HE12 and the second horizontal edge HE21 and HE22 are not arranged in the same line in the horizontal direction. The first horizontal edge HE11 and HE12, the second horizontal edge HE21 and HE22, and the first vertical edge VE1 define corner portions CI and CO. The corner portions CI and CO may include, for example, the inner corner CI and the outer corner CO.

The first horizontal edge HE11 and HE12 include a first-first horizontal edge HE11 and a first-second horizontal edge HE12. The second horizontal edge HE21 and HE22 include a second-first horizontal edge HE21 and a second-second horizontal edge HE22. The first-second horizontal edge HE12 is connected to one end of the first vertical edge VE1 while the second-first horizontal edge HE21 is connected to the other end of the first vertical edge VE1. The first-second horizontal edge HE12 and the first vertical edge VE1 define the inner corner CI, while the second-first horizontal edge HE21 and the first vertical edge VE1 define the outer corner CO. The inner corner CI and the outer corner CO may be adjacent to each other in the vertical direction. The inner corner CI may have an internal angle of 270 degrees, and the outer corner CO may have an internal angle of 90 degrees. Each of the first-second horizontal edge HE12, the first vertical edge VE1, and the second-first horizontal edge HE21 may be referred to as a step edge.

The first-first horizontal edge HE11 extends in the horizontal direction DR1 and is disposed at the second extension ER2. The second-second horizontal edge HE22 extends in the horizontal direction DR1 and is disposed at the first extension ER1.

For example, the first target pattern TP1 includes straight edges HE11, HE12, VE1, HE21, and HE22.

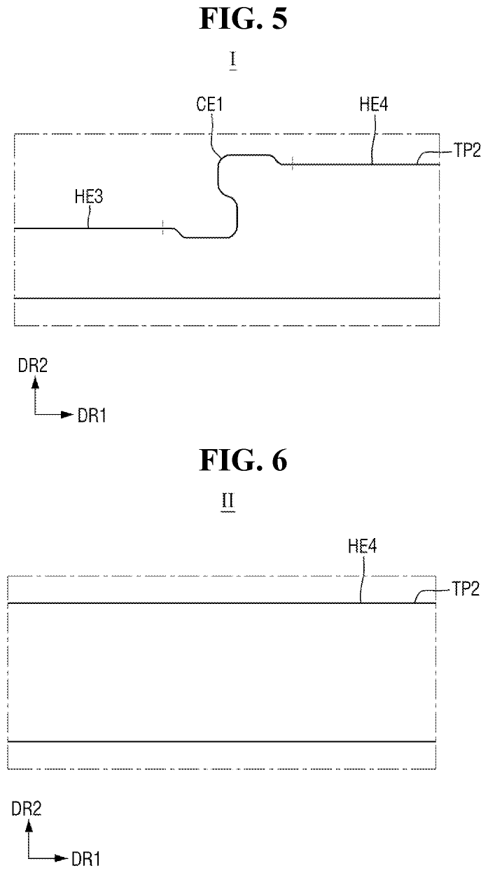

Referring to FIG. 1, FIG. 5 and FIG. 6, a second target pattern TP2 is generated from the first target pattern TP1 in S120.

The second target pattern TP2 is generated by changing each of the corner portions CI and CO of the first target pattern TP1 into a curve. The second target pattern TP2 is generated by changing an edge directly connected to the corner of the transition TR into a curve. The curve may be generated in accordance with various schemes.

The second target pattern TP2 is generated by changing each of the edges HE12, HE21, and VE1, for example, the step edges constituting the corner portions CI and CO of the first target pattern TP1 into a curve. The first-second horizontal edge HE12, the first vertical edge VE1, and the second-first horizontal edge HE21, for example, the step edges defining the corner portions CI and CO are changed to a first curved edge CE1. Accordingly, the second target pattern TP2 includes a third horizontal edge HE3, the first curved edge CE1, and a fourth horizontal edge HE4. The first curved edge CE1 may have, for example, a first portion connected to the fourth horizontal edge HE4 and convex in a first direction and a second portion connected to the third horizontal edge HE3 and convex in a second direction. The first direction and the second direction may be different from each other. The first direction may be a direction outwardly of the second target pattern TP2 and the second direction may be a direction inwardly of the second target pattern TP2.

The third horizontal edge HE3 of the second target pattern TP2 is the same as the first-first horizontal edge HE11 of the first target pattern TP1. The fourth horizontal edge HE4 of the second target pattern TP2 is the same as the second-second horizontal edge HE22 of the first target pattern TP1. The third horizontal edge HE3 extends in the horizontal direction DR1 and is disposed at the second extension ER2. The fourth horizontal edge HE4 extends in the horizontal direction DR1 and is disposed at the first extension ER1. A portion of the second target pattern TP2, except for the first curved edge CE1, may be substantially the same as a portion of the first target pattern TP1, except for the corner portions CI and CO.

For example, the second target pattern TP2 includes the straight edges HE3 and HE4 and the first curved edge CE1. The transition TR of the second target pattern TP2 includes the straight edges HE3 and HE4 and the first curved edge CE1, while each of the first extension ER1 and the second extension ER2 of the second target pattern TP2 includes each of the straight edges HE3 and HE4.

A length of each of the first-second horizontal edge HE12 and the second-first horizontal edge HE21 of the first target pattern TP1 that are changed to the first curved edge CE1 may vary according to a predetermined value.

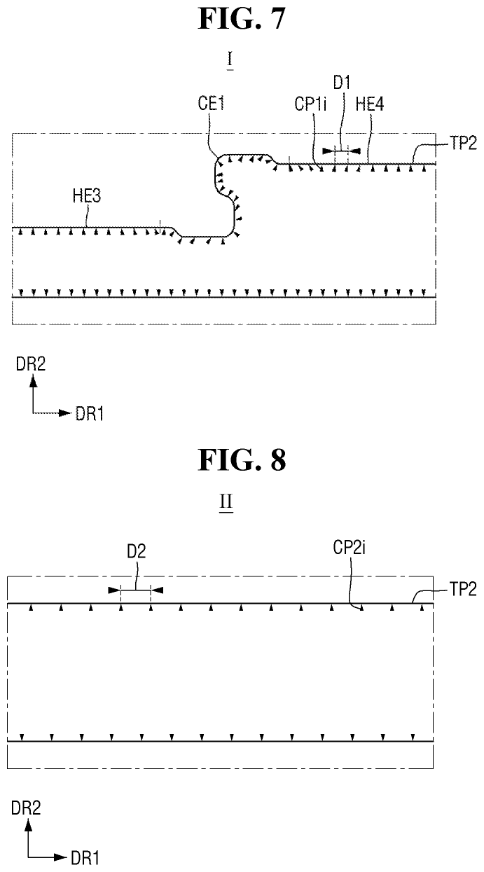

Referring to FIG. 1, FIG. 7, and FIG. 8, optical proximity correction is performed on the second target pattern TP2 to generate a mask pattern MP in S130.

Initial mask control points CP1i and CP2i are generated on the second target pattern TP2. The first initial mask control point CP1i is generated on the transition TR of the second target pattern TP2. The second initial mask control point CP2i is generated on each of the first extension ER1 and the second extension ER2 of the second target pattern TP2. Although it is shown in FIG. 8 that the second mask control point CP2i is disposed on the first extension ER1, the second mask control point CP2i is generated on the second extension ER2.

A first initial spacing D1 between two first initial mask control points CP1i adjacent to each other in the horizontal direction DR1 may be different from a second initial spacing D2 between two second initial mask control points CP2i adjacent to each other in the horizontal direction DR1. The first initial spacing D1 may be smaller than the second initial spacing D2.

An arrangement density of the first initial mask control points CP1i may be different from an arrangement density of the second initial mask control points CP2i. The arrangement density of the first initial mask control point CP1i may be greater than the arrangement density of the second initial mask control point CP2i. In this regard, the arrangement density may mean the number of mask control points per a unit length of an edge.

Each of the arrangement density of the first initial mask control points CP1i, the arrangement density of the second initial mask control point CP2i, and the first initial spacing D1 and the second initial spacing D2 may vary according to each of a number of predetermined values.

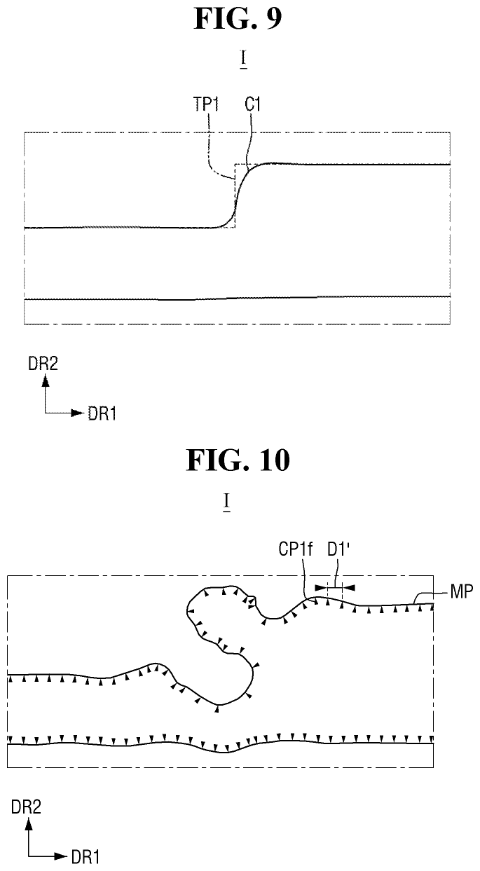

Referring to FIG. 9, mask data about the second target pattern TP2 may be input to an optical proximity correction model which in turn performs simulation to extract a contour C1 of the second target pattern TP2. FIG. 9 shows the contour C1 of the transition TR. However, the contour C1 of each of the first extension ER1 and the second extension ER2 is also extracted.

Various basic data may be input to the optical proximity correction model. The basic data may include mask data about a fragment or the mask control point (e.g., CP1i and CP2i). Furthermore, the basic data may include numerical data such as a thickness, a refractive index, and a dielectric constant of PR (Photo Resist), and may include data of a source map about an illumination system shape. The basic data are not necessarily limited to the data as exemplified above. In one example, the mask data may include not only the fragment data, but also data such as a shape of patterns, a position of patterns, a measurement type (space or line measurement) of patterns, and basic measurement values.

It is determined whether the contour C1 of the second target pattern TP2 satisfies a reference condition or whether the number of times the optical proximity correction is performed is a reference count. The reference condition may include an error range between the contour C1 of the second target pattern TP2 and the first target pattern TP1, MRC (Mask Rule Check), and an allowable range of a corner rounding radius.

The contour C1 of the second target pattern TP2 may correspond to a shape of a pattern formed on the wafer in an exposure process using a photomask. For example, a shape of the contour C1 of the second target pattern TP2 may be transferred onto a substrate.

When the contour C1 of the second target pattern TP2 does not satisfy the reference condition, the second target pattern TP2 may be updated. For example, the second target pattern TP2 may be updated using the first target pattern TP1 and the contour C1 of the second target pattern TP2. The second target pattern TP2 may be updated using a difference value between the first target pattern TP1 and the contour C1 of the second target pattern TP2. For example, the second target pattern TP2 may be updated by displacing the initial mask control points CP1i and CP2i in various directions, and then connecting the displaced mask control points CP1i and CP2i to each other.

The second target pattern TP2 may be repeatedly updated until the second target pattern TP2 satisfies the reference condition. For example, the initial mask control points CP1i and CP2i may be repeatedly displaced.

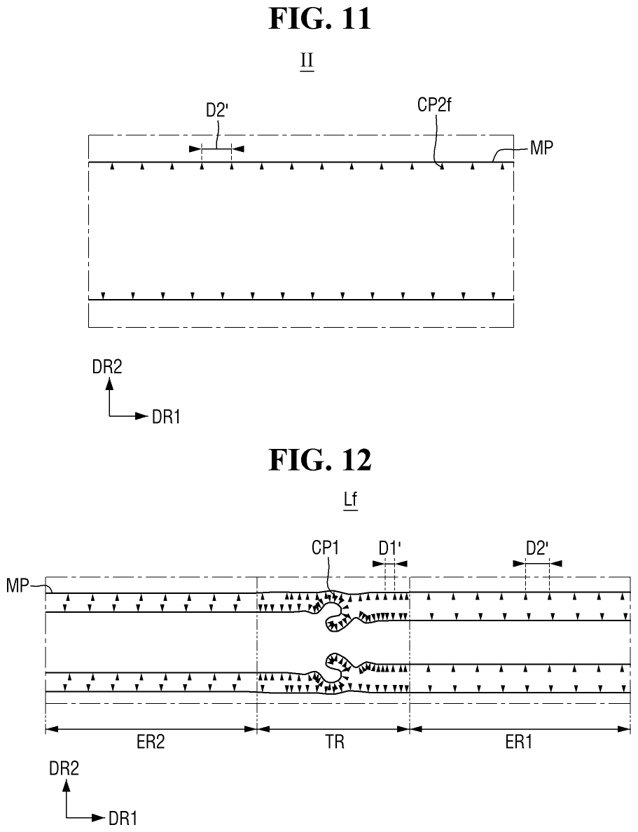

Referring to FIG. 1, FIG. 10 and FIG. 11, when the contour C1 of the second target pattern TP2 satisfies the reference condition, the mask pattern MP is determined in S130.

For example, the mask pattern MP may be generated by connecting final mask control points CP1f and CP2f to each other. The first initial mask control point CP1i may be updated to generate the first final mask control point CP1f, and the second initial mask control point CP2i may be updated to generate the second final mask control point CP2f.

A first final spacing D1′ between two first final mask control points CP1f adjacent to each other in the horizontal direction DR1 may be different from a second final spacing D2′ between two second final mask control point CP2f adjacent to each other in the horizontal direction DR1. The first final spacing D1′ may be smaller than the second final spacing D2′.

An arrangement density of the first final mask control points CP1f may be different from an arrangement density of the second final mask control points CP2f. The density of the first final mask control points CP1f may be greater than the density of the second final mask control points CP2f.

Referring to FIG. 12, a final layout Lf including the mask pattern MP is generated accordingly. In this way, a mask may be fabricated using the final layout Lf including the mask pattern MP.

A first optical proximity correction may be performed on a first target pattern to generate an intermediate target pattern composed of a vertical edge and a horizontal edge. Then, a second target pattern may be generated by changing the edge of the intermediate target pattern into a curve. Then, a mask control point may be generated on the second target pattern. Then, a second optical proximity correction may be performed thereon to generate a mask pattern. The second target pattern may be composed of curved edges. When the optical proximity correction is performed, the mask control points may be arranged on the second target pattern and may be spaced from each other by a predetermined spacing.

However, in the method for fabricating the mask according to some embodiments, the second target pattern TP2 is generated by changing only the corner portion CI and CO of the first target pattern TP1 into a curve. Thus, the step of generating the intermediate target pattern is omitted, such that a fabricating time in the method for fabricating the mask may be reduced.

In addition, in the method for fabricating the mask, according to some embodiments, the first extension ER1 and the second extension ER2 of the first target pattern TP1 may respectively be the same as the first extension ER1 and the second extension ER2 of the second target pattern TP2. Each of the first extension ER1 and the second extension ER2 includes the straight edges. The transition TR of the second target pattern TP2 has a different shape from that of the transition TR of the first target pattern TP1 and has the curved edge. Therefore, the density of the first initial mask control points CP1i generated on the transition TR may be higher than that of the second initial mask control points CP2i generated ono each of the first extension ER1 and the second extension ER2. Accordingly, the mask pattern MP more approximate to the first target pattern TP1 may be generated. Further, the number of mask control points may be reduced compared to that in a case in which the second target pattern is composed only of curved edges. Accordingly, a time for performing the optical proximity correction control may be reduced, so that the fabricating time in the method for fabricating the mask may be reduced. Further, a file size of the mask pattern may be reduced because the number of mask control points is reduced.

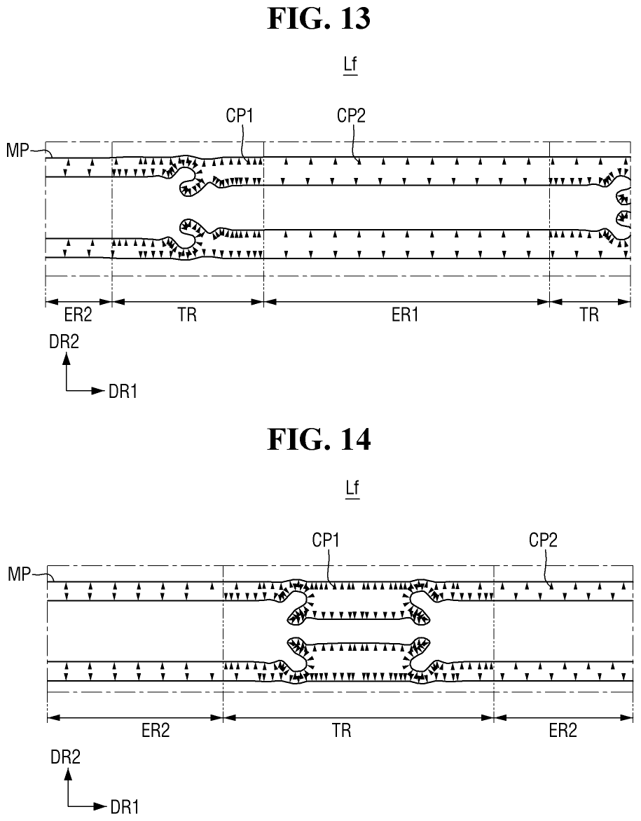

FIG. 13 and FIG. 14 are diagrams for illustrating a method for fabricating a mask according to some embodiments.

Referring to FIG. 13 and FIG. 14, various mask patterns MP may be generated according to a method for fabricating a mask according to some embodiments.

Referring to FIG. 13, the mask pattern MP of the final layout Lf may include a plurality of transitions TR. For example, the second extension ER2, a first transition TR, the first extension ER1, and a second transition TR may be sequentially connected to each to each other.

Referring to FIG. 14, two transitions TR may be directly connected to each other, and thus the first extension ER1 may be omitted.

Referring to FIG. 13 and FIG. 14, the density of the first mask control points CP1 disposed on the transition TR may be greater than the density of the second mask control points CP2 disposed on each of the first extension ER1 and the second extension ER2.

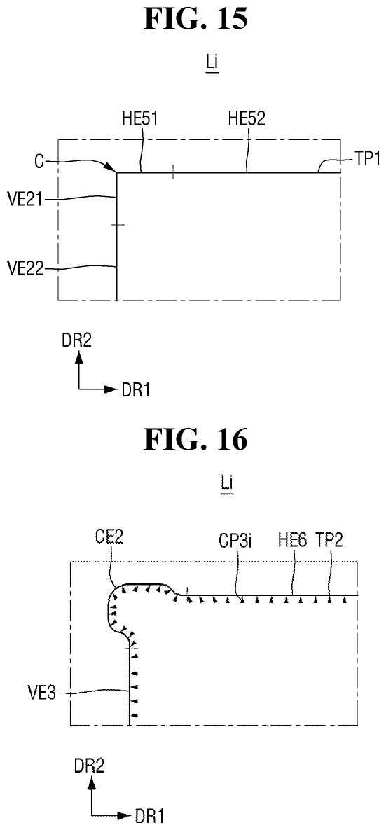

FIG. 15 and FIG. 16 are diagrams for illustrating a method for fabricating a mask according to some embodiments.

Referring to FIG. 15, the first target pattern TP1 is generated from the design pattern included in the initial layout Li. The first target pattern TP1 includes an extension extending in the horizontal direction DR1 and/or the vertical direction DR2 and a transition including a corner portion. FIG. 15 is a diagram showing the transition of the first target pattern TP1.

The first target pattern TP1 includes a fifth horizontal edge HE51 and HE52 and a second vertical edge VE21 and VE22. The second vertical edge VE21 and VE22 is connected to the fifth horizontal edge HE51 and HE52. The fifth horizontal edge HE51 and HE52 and the second vertical edge VE21 and VE22 define a corner portion C.

The fifth horizontal edge HE51 and HE52 include a fifth-first horizontal edge HE51 and a fifth-second horizontal edge HE52. The second vertical edge VE21 and VE22 includes a second-first vertical edge VE21 and a second-second vertical edge VE22. The fifth-first horizontal edge HE51 and the second-first vertical edge VE21 are connected to each other. The fifth-first horizontal edge HE51 and the second-first vertical edge VE21 define the corner portion C. The corner portion C may have an internal angle of 90 degrees.

Referring to FIG. 15 and FIG. 16, the second target pattern TP2 is generated from the first target pattern TP1. The second target pattern TP2 is generated by changing the corner portion C of the first target pattern TP1 into a curve. The second target pattern TP2 is generated by changing the edges HE51 and VE21 defining the corner portion C of the first target pattern TP1 into a curve. The fifth-first horizontal edge HE51 and the second-first vertical edge VE21 defining the corner portion C are changed to a second curved edge CE2. Accordingly, the second target pattern TP2 includes a third vertical edge VE3, the second curved edge CE2, and a sixth horizontal edge HE6. The second curved edge CE2 may have, for example, a curve protruding outwardly of the second target pattern TP2.

The third vertical edge VE3 of the second target pattern TP2 is the same as the second-second vertical edge VE22 of the first target pattern TP1, and the sixth horizontal edge HE6 of the second target pattern TP2 is the same as the fifth-second horizontal edge HE52 of the first target pattern TP1.

A length of each of the fifth-first horizontal edge HE51 and the second-first vertical edge VE21 of the first target pattern TP1 that are changed to the second curved edge CE2 may vary according to a predetermined value.

A third initial mask control point CP3i is generated on the second target pattern TP2. A mask pattern is generated by performing the optical proximity correction on the second target pattern TP2. For example, a density of the third initial mask control points CP3i generated on the extension of the second target pattern TP2 may be smaller than a density of the third initial mask control points CP3i generated on the transition of the second target pattern TP2. Each of the density of the third initial mask control points CP3i generated on the extension of the second target pattern TP2 and the density of the third initial mask control points CP3i generated on the transition of the second target pattern TP2 may vary according to a predetermined value.

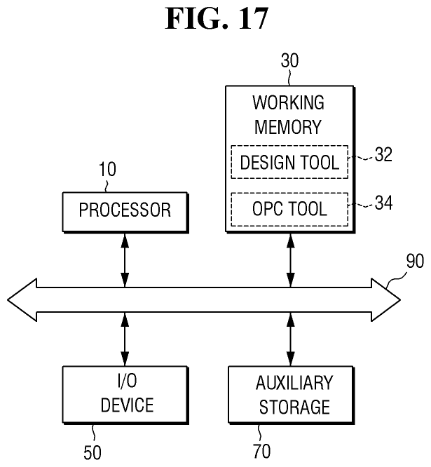

FIG. 17 is a block diagram showing a mask fabricating device according to some embodiments.

Referring to FIG. 17, the mask fabricating device includes a processor 10, a working memory 30, an input/output device 50, an auxiliary storage device 70, and a system interconnector 90 (e.g., a data bus).

For example, the mask fabricating device may be provided as a dedicated device for a method for fabricating a mask according to some embodiments or as a dedicated device for performing a semiconductor design including the same. For example, the mask fabricating device may have various design and verification simulation programs.

The processor 10 may execute software (e.g., an application program, an operating system, and a device drivers) to be executed on the mask fabricating device. The processor 10 may execute the operating system OS loaded into the working memory 30. The processor 10 may execute various application programs to be driven based on the operating system. For example, the processor 10 may be a CPU (central processing unit), a microprocessor, AP (application processor), or any similar processing device.

The operating system or the application programs may be loaded into the working memory 30. In booting the mask fabricating device, an OS image stored in the auxiliary storage device 70 may be loaded into the working memory 30 according to a booting sequence. All input/output operations of the mask fabricating device may be supported by the operating system. Similarly, the application programs which may be selected by the user or may provide a basic service may be loaded into the working memory 30. In particular, a design tool 32 for the above-described semiconductor design, and/or an OPC tool 34 for the method for fabricating the mask according to the present disclosure may be loaded from the auxiliary storage device 70 into the working memory 30.

The design tool 32 may have a bias function that may change a shape and a position of specific layout patterns so as to be different from those defined by a design rule. Furthermore, the design tool 32 may perform design rule check (DRC) under the changed bias data condition. For example, the working memory 30 may be a volatile memory such as DRAM (dynamic random access memory), SRAM (static random access memory), or may be a non-volatile memory such as a flash memory, PRAM (phase change random access memory), RRAM (resistance random access memory), NFGM (nano floating gate memory), PoRAM (polymer random access memory), MRAM (magnetic random access memory), FRAM (ferroelectric random access memory), or the like.

The input/output device 50 may control user input and output from and into user interface devices. For example, the input/output device 50 may be equipped with input means such as a keyboard, a keypad, a mouse, a touch screen, etc., and may receive information from a designer. Using the input/output device 50, a user may receive information about a semiconductor area requiring adjusted operating characteristics, or data paths. Furthermore, the input/output device 50 may include output means such as a printer or a display to display a process and a process result of the design tool 32 and/or the OPC tool 34.

The auxiliary storage device 70 may be provided as a storage medium of the mask fabricating device. The auxiliary storage device 70 may store therein the application programs, the OS image, and various data. The auxiliary storage device 70 may be provided in a form of a mass storage device such as a memory card (MMC, cMMC, SD, MicroSD, etc.), HDD (hard disk drive), SSD (solid state drive), UFS (universal flash storage), or the like.

The system interconnector 90 may be a system bus (e.g., a data bus) for providing a network in the mask fabricating device. Via the system interconnector 90, the processor 10, the working memory 30, the input/output device 50, and the auxiliary storage device 70 may be electrically connected to each other and may exchange data with each other. However, a configuration of the system interconnector 90 is not necessarily limited to the above description, and may further include mediation means for efficient management.

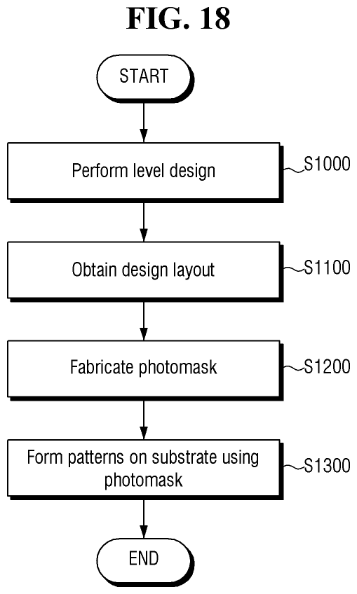

FIG. 18 is a flow chart illustrating a method for manufacturing a semiconductor device in accordance with some embodiments.

Referring to FIG. 18, a high-level design of the semiconductor device is performed in S1000.

The high-level design may describe an integrated circuit to be designed in a high-level language of a computer language. For example, the high-level language such as the C language may be used. Circuits designed in the high-level design may be expressed more specifically by register transfer level (RTL) coding or simulation. Furthermore, a code generated by the register transfer level coding may be converted into a netlist which in turn may be synthesized into a schematic circuit. The synthesized schematic circuit is verified by a simulation tool, and an adjustment process may be performed according to the verification result.

A design layout of a layer included in the semiconductor device is obtained in S1100. The design layout may be the initial layout LO as shown in FIG. 2.

A layout design for implementing a logically completed semiconductor device on a silicon substrate may be performed. For example, the layout design may be performed with referring to the schematic circuit synthesized in the high-level design or the netlist corresponding thereto. The layout design may include a routing procedure that places and connects various standard cells provided from a cell library to each other according to a prescribed design rule.

The cell library for the layout design may further contain information on an operation, a speed, and power consumption of the standard cell. A cell library for expressing a circuit of a specific gate level into a layout is defined in most of layout design tools.

The layout may be a procedure for defining a shape or a size of a pattern constituting a transistor and a metal wire to be actually formed on a silicon substrate. For example, in order to actually form an inverter circuit on the silicon substrate, layout patterns such as PMOS, NMOS, N-WELL, gate electrodes, and metal wires to be disposed thereon may be properly placed. To this end, a suitable inverter may be searched for and selected from among inverters already defined in the cell library.

In addition, routing may be performed on the selected and placed standard cells. For example, routing of the selected and standard cells with higher level wires may be performed. The standard cells may be connected to each other according to the design in the routing procedure. Most of a series of processes in S1000 and S1100 as described above may be performed automatically or manually using the design tool 32 of FIG. 17. Furthermore, the placement and routing of the standard cells may be automatically performed using a separate Place & Routing tool.

After the routing, the layout may be verified to check whether a portion which violates the design rule is present. The verification may include DRC (Design Rule Check) which verifies whether the layout complies with the design rule, ERC (Electrical Rule Check) which verifies whether electrical disconnection occurs, and LVS (Layout vs Schematic) which verifies whether the layout matches the gate level netlist, etc.

The photomask is fabricated in S1200. S1200 may be performed by the method for fabricating the mask as described above with reference to FIG. 1 to FIG. 16.

The optical proximity correction may be performed on the design layout to generate an updated design layout. The updated design layout may be the final layout Lf including the mask pattern MP as shown in FIG. 10 to FIG. 14.

Based on the design layout updated by the optical proximity correction, the photomask is fabricated. In general, the photomask may be fabricated in a scheme of depicting layout patterns using a chromium film applied on a glass substrate. However, the present disclosure is not necessarily limited thereto.

A pattern may be formed on a substrate using the photomask in S1300. In this way, the semiconductor device may be manufactured.

In the manufacturing process of the semiconductor device using the photomask, exposure and etch processes in various manners may be repeated. In these repeated processes, shapes of the patterns constructed during the layout design may be sequentially formed on the silicon substrate.

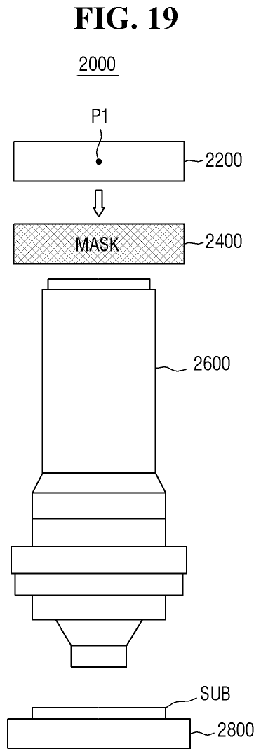

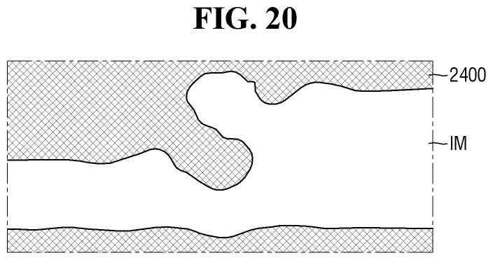

FIG. 19 is a block diagram illustrating a photolithography system for performing a method for manufacturing a semiconductor device according to some embodiments.

Referring to FIG. 19, a photolithography system 2000 may include a light source 2200, a photomask 2400, a reduction projection device 2600 and a substrate stage 2800.

However, the photolithography system 2000 may further include components not as shown in FIG. 11. For example, the photolithography system 2000 may further include a sensor used to measure a height and a tilt of a surface of a substrate SUB.

The light source 2200 may emit light. The light emitted from the light source 2200 may

be cast onto the photomask 2400. For example, a lens may be provided between the light source 2200 and the photomask 2400 to adjust a light focus. The light source 2200 may include an ultraviolet light source (for example, a KrF light source with a wavelength of about 234 nm, an ArF light source with a wavelength of about 193 nm, and the like). The light source 2200 may include one point light source P1. However, the present disclosure is not necessarily limited thereto. In some embodiments, the light source 2200 may include a plurality of point light sources.

In order to print (e.g., implement) a designed layout on the substrate SUB, the photomask 2400 may include image patterns. The image patterns may include a transparent area and an opaque area. The transparent area may be formed by etching a metal layer (for example, a chromium film) on the photomask 2400. The light emitted from the light source 2200 may extend through the transparent area. On the contrary, the opaque area may block light.

The reduction projection device 2600 may receive light which has passed through the transparent area of the photomask 2400. The reduction projection device 2600 may match layout patterns to be printed on the substrate SUB with the image patterns of the photomask 2400. The substrate stage 2800 may support the substrate SUB. For example, the substrate SUB may include a silicon wafer.

The reduction projection device 2600 may include an aperture. The aperture may be used to increase a depth of focus of the light emitted from the light source 2200. For example, the aperture may include a dipole aperture or a quadruple aperture. The reduction projection device 2600 may further include a lens to adjust the light focus.

The transparent area included in the image patterns of the photomask 2400 may transmit the light emitted from the light source 2200 therethrough.

The light which has passed through the photomask 2400 may be cast to the substrate SUB through the reduction projection device 2600. Thus, the patterns corresponding to the image patterns of the photomask 2400 may be printed on the substrate SUB.

As integration of the semiconductor device increases, a distance between the image patterns of the photomask 2400 becomes very smaller and a width of the transparent area becomes very smaller. Due to this “proximity”, light interference and diffraction occur, and thus a distorted layout different from a target layout may be printed on the substrate SUB. When the distorted layout is printed on the substrate SUB, the designed circuit may operate abnormally.

In order to prevent the layout distortion, a resolution enhancement technique may be used. The optical proximity correction is an example of the resolution enhancement technique. According to the optical proximity correction, an amount of the distortion such as the interference and diffraction of light may be predicted. Furthermore, based on the predicted result, image patterns to be formed on the photomask 2400 may be pre-biased. Thus, a desired layout may be printed on the substrate SUB.

In one embodiment, the optical proximity correction may be performed to adjust a layout of a single layer. In one example, in a semiconductor process, the semiconductor device may be implemented to include a plurality of layers. For example, the semiconductor device may include a stack of a plurality of metal layers to implement a specific circuit. Accordingly, the optical proximity correction may be independently performed on each of the plurality of layers.

Alternatively, when EUV (extreme ultraviolet) is used as the light source 2200, a configuration of the photolithography system 2000 may be changed accordingly.

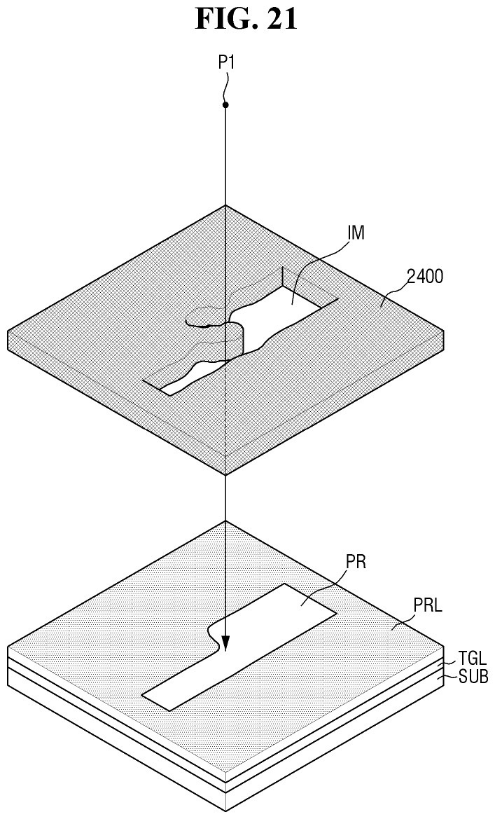

FIG. 20 is a diagram showing an example of a photomask included in the photolithography system of FIG. 19. FIG. 21 is a diagram showing printing of a circuit pattern on a substrate using the photomask of FIG. 20.

Referring to FIG. 20, a photomask 2400 may include an image pattern IM corresponding to the mask pattern MP of FIG. 10. The photomask 2400 may include a transparent area and an opaque area. The opaque area may block light. On the contrary, the transparent area may transmit therethrough the light emitted from the light source 2200 of FIG. 19. The light which has passed through the photomask 2400 may be cast onto the substrate SUB of FIG. 19. For example, in a photolithography process using a negative photoresist, the image pattern IM may be a transparent area of the photomask 2400.

Referring to FIG. 21, a point light source PI of the light source 2200 in FIG. 19 may emit light to the photomask 2400. The emitted light may transmit through the transparent area of the image pattern IM and be cast onto a photoresist layer PRL on the substrate SUB (e.g., exposure process). An area of the photoresist layer PRL onto which the light is cast may become the photoresist pattern PR. The photoresist pattern PR may be formed in the same shape and size as those of the contour C1 of the mask pattern MP as described above. FIG. 20 and FIG. 21 shows an example in which an inner corner and an outer corner of the image pattern IM are formed by the method for fabricating the mask according to some embodiments. However, a corner of an end of the image pattern IM having an inner angle of 90 degrees may also be manufactured by the method for fabricating the mask according to some embodiments.

Then, a developing process may be performed such that the photoresist pattern PR may remain and a remaining photoresist layer PRL may be removed (although in some embodiments the reverse may be true). The remaining photoresist pattern PR may be used as an etch mask in patterning an etch target layer TGL on the substrate SUB. Thus, desired target patterns may be formed on the substrate SUB. As a result, the target patterns may be formed on each layer (in S1300 in FIG. 18). In this way, the semiconductor device may be manufactured.

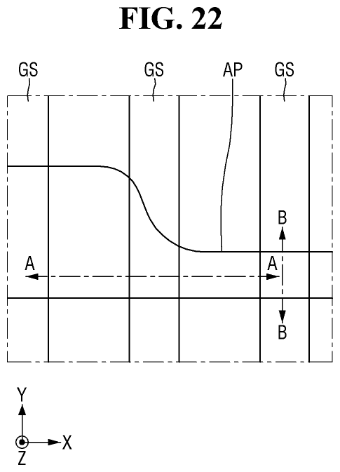

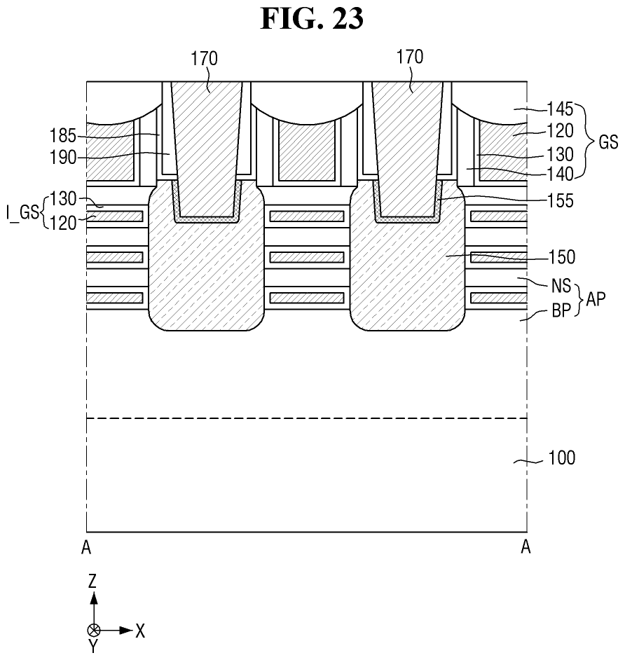

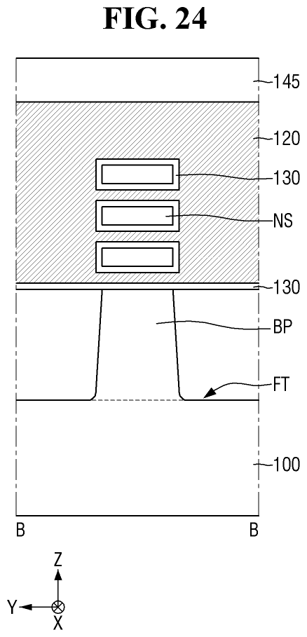

FIG. 22 to FIG. 24 are diagrams for illustrating a semiconductor device according to some embodiments. FIG. 23 is a cross-sectional view taken along A-A of FIG. 22. FIG. 24 is a cross-sectional view taken along B-B of FIG. 22.

Referring to FIG. 22 to FIG. 24, the semiconductor device, according to some embodiments, may include a substrate 100, an active pattern AP, a field insulating film 105, a gate structure GS, a source/drain pattern 150, a source/drain contact 170, and a source/drain etch stop film 185.

The substrate 100 may be made of a semiconductor material or may include a semiconductor material. The substrate 100 may be a silicon substrate or an SOI (silicon-on-insulator) substrate. Alternatively, the substrate 100 may include, for example, silicon germanium, SGOI (silicon germanium on insulator), indium antimonide, lead telluride compound, indium arsenide, indium phosphide, gallium arsenide, or gallium antimonide. However, the present disclosure is not necessarily limited thereto.

The active pattern AP may be disposed on the substrate 100. The active pattern AP may extend in an elongate manner in a first direction X. The active pattern AP may be a multi-channel active pattern. The active pattern AP may include a lower pattern BP and a plurality of sheet patterns NS. The lower pattern BP may protrude from the substrate 100. The lower pattern BP may extend in an elongate manner in the first direction X. A sidewall of the lower pattern BP may be defined by a fin trench FT. The active pattern AP may be formed by the method for manufacturing the semiconductor device according to some embodiments as described above.

The plurality of sheet patterns NS may be disposed on the lower pattern BP. The plurality of sheet patterns NS may be spaced apart from an upper surface of the lower pattern BP in a third direction Z. The sheet patterns NS may be spaced apart from each other in the third direction Z. Although it is shown that three sheet patterns NS are arranged in the third direction Z, this is for convenience of illustration. However, the present disclosure is not necessarily limited thereto. A width in a second direction Y of the sheet pattern NS may increase or decrease in proportion to a width in a second direction Y of the lower pattern BP.

In this regard, the first direction X may intersect the second direction Y and the third direction Z. Furthermore, the second direction Y may intersect with the third direction Z. The third direction Z may be a thickness direction of the substrate 100.

The lower pattern BP may be formed by etching a portion of the substrate 100, or may include an epitaxial layer grown from the substrate 100. The lower pattern BP may include an elemental semiconductor material such as silicon or germanium. Furthermore, the lower pattern BP may include a compound semiconductor, for example, a group IV-IV compound semiconductor or a group III-V compound semiconductor. The sheet pattern NS may include one of the elemental semiconductor material such as silicon or germanium, the group IV-IV compound semiconductor or the group III-V compound semiconductor.

The field insulating film 105 is disposed on the substrate 100. The field insulating film 105 may be disposed on a sidewall of the lower pattern BP. The field insulating film 105 is not disposed on an upper surface of the lower pattern.

A plurality of gate structures GS may be disposed on the substrate 100. Each gate structure GS may extend in the second direction Y. The gate structures GS may be spaced apart from each other in the first direction X. The gate structures GS may be adjacent to each other in the first direction X. For example, the gate structure GS may be disposed on each of both opposing sides in the first direction X of the source/drain pattern 150.

The gate structure GS may be disposed on the active pattern AP. The gate structure GS may intersect the active pattern AP. The gate structure GS may intersect the lower pattern BP. The gate structure GS may at least partially surround each sheet pattern NS. The gate structure GS may include, for example, a gate electrode 120, a gate insulating film 130, a gate spacer 140, and a gate capping pattern 145.

The gate structure GS may include a plurality of inner gate structures INT1_GS respectively disposed between adjacent ones in the third direction Z of sheet patterns NS and between the lower pattern BP and the lowest sheet pattern NS. The inner gate structures I_GS may be respectively disposed between the upper surface of the lower pattern BP and the lower surface of the lowest sheet pattern NS, and between an upper surface of the sheet pattern NS and a lower surface of the sheet pattern NS facing each other in the third direction Z.

The gate electrode 120 may be disposed on the lower pattern BP. The gate electrode 120 may intersect with the lower pattern BP. The gate electrode 120 may at least partially surround the sheet pattern NS. A portion of the gate electrode 120 may be disposed between adjacent sheet patterns NS and between the lower pattern BP and the lowest sheet pattern NS. The gate electrode 120 may include at least one of a metal, a metal alloy, a conductive metal nitride, a metal silicide, a doped semiconductor material, a conductive metal oxide, or a conductive metal oxynitride.

The gate insulating film 130 may extend along the upper surface of the field insulating film 105 and the upper surface of the lower pattern BP. The gate insulating film 130 may at least partially surround the plurality of sheet patterns NS. The gate insulating film 130 may be disposed along a profile of the sheet pattern NS. The gate electrode 120 is disposed on the gate insulating film 130. The gate insulating film 130 is disposed between the gate electrode 120 and the sheet pattern NS. A portion of the gate insulating film 130 may be disposed between adjacent ones in the third direction Z of the sheet patterns NS and between the lower pattern BP and the lowest sheet pattern NS. The gate insulating film 130 may include silicon oxide, silicon oxynitride, silicon nitride, or a high-k material having a higher dielectric constant than that of silicon oxide. Although the gate insulating film 130 is illustrated as a single film, this is for convenience of illustration, and the present disclosure is not necessarily limited thereto. The gate insulating film 130 may include a plurality of films.

The semiconductor device, according to some embodiments, may include an NC (Negative Capacitance) FET using a negative capacitor. For example, the gate insulating film 130 may include a ferroelectric material film having ferroelectric characteristics and a paraelectric material film having paraelectric characteristics.

A gate spacer 140 may be disposed on a sidewall of the gate electrode 120. The gate spacer 140 might not be disposed between the lower pattern BP and the lowest sheet pattern NS and between the sheet patterns NS adjacent to each other in the third direction Z. The gate spacer 140 may include, for example, at least one of SiN (silicon nitride), SiON (silicon oxynitride), SiO₂ (silicon oxide), SiOCN (silicon oxycarbonitride), SiBN (silicon boron nitride), SiOBN (silicon oxyboronitride), SiCO (silicon oxycarbide), or combinations thereof. Although the gate spacer 140 is shown as a single film, this is for convenience of illustration, and the present disclosure is not necessarily limited thereto.

A gate capping pattern 145 may be disposed on the gate electrode 120. The gate capping pattern 145 may be disposed between the gate spacers 140. The gate capping pattern 145 may include, for example, at least one of silicon nitride, silicon oxynitride, silicon carbonitride, silicon oxycarbonitride, or combinations thereof.

The source/drain pattern 150 may be disposed on the active pattern AP. The source/drain pattern 150 may be disposed on the lower pattern BP. The source/drain pattern 150 may be disposed on a side surface of the gate structure GS. The source/drain pattern 150 may be included in a source/drain of a transistor using the sheet pattern NS as a channel area. The source/drain pattern 150 may include an epitaxial pattern. The source/drain pattern 150 may include a semiconductor material.

The source/drain etch stop film 185 may extend along an outer wall of the gate spacer 140 and a profile of the source/drain pattern 150. The source/drain etch stop film 185 may be disposed on the upper surface of the field insulating film 105. The source/drain etch stop film 185 may include, for example, at least one of silicon nitride, silicon oxynitride, silicon oxycarbonitride, silicon boron nitride, silicon oxyboronitride, silicon oxycarbide, or combinations thereof.

An interlayer insulating film 190 may be disposed on the source/drain etch stop film 185. The interlayer insulating film 190 may be disposed on the source/drain pattern 150. The interlayer insulating film 190 might not cover an upper surface of the gate capping pattern 145. For example, an upper surface of the interlayer insulating film 190 may be coplanar with an upper surface of the gate capping pattern 145. The interlayer insulating film 190 may include, for example, at least one of silicon oxide, silicon nitride, silicon oxynitride, or a low dielectric constant material.

The source/drain contact 170 is disposed on the source/drain pattern 150. The source/drain contact 170 is connected to the source/drain pattern 150. The source/drain contact 170 may extend through the interlayer insulating film 190 and the source/drain etch stop film 185 so as to be connected to the source/drain pattern 150. The source/drain contact 170 is shown as a single film. However, this is for convenience of illustration, and the present disclosure is not necessarily limited thereto. The source/drain contact 170 may include at least one of, for example, a metal, a metal alloy, a conductive metal nitride, a conductive metal carbide, a conductive metal oxide, a conductive metal carbonitride, or a two-dimensional (2D) material.

A metal silicide layer 155 may be further disposed between the source/drain contact 170 and the source/drain pattern 150.

Referring to FIG. 22, the active pattern AP includes a first extension and a second extension extending in the first direction X, and a transition connecting the first extension and the second extension to each other. The first extension and the second extension have different widths in the second direction Y. The width of the transition in the second direction Y may decrease as the transition extends in the first direction X.

In this regard, as a length in the first direction X of the transition of the active pattern AP (a length of an area in which a width in the second direction Y is changed) increases or an inclination angle of the transition of the active pattern AP with respect to the second direction Y increases, a distance between the active pattern AP (for example, the source/drain pattern 150) and the gate structure GS becomes smaller. Accordingly, a defect in the semiconductor device may occur.

However, the active pattern AP may be formed using the mask formed by the method for fabricating the mask according to some embodiments. Accordingly, the active pattern AP may have a shape more approximate to that of the design pattern. The transition of the active pattern AP may be more approximate to a step shape having a corner of 90 degrees, and thus the length in the first direction X of the transition may be smaller. As a result, the distance between the active pattern AP and the gate structure GS may be increased, thereby preventing the defect in the semiconductor device.

Although embodiments of the present disclosure have been described with reference to the accompanying drawings, the present disclosure is not necessarily limited to the above embodiments, but may be implemented in various different forms. A person skilled in the art may appreciate that the present disclosure may be practiced in other concrete forms without changing the technical spirit or essential characteristics of the present disclosure.

1. A method for fabricating a mask, the method comprising:
receiving a first target pattern that includes first straight edges;
generating a second target pattern from the first target pattern, wherein the second target pattern includes second straight edges and curved edges;
performing optical proximity correction on the second target pattern to generating a mask pattern therefrom; and
fabricating the mask using the mask pattern,
wherein generating the second target pattern includes changing corner portions of the first target pattern into a curve to generate the curved edges.

2. The method of claim 1, wherein each of the first straight edges and each of the second straight edges is a horizontal edge extending in a horizontal direction or a vertical edge extending in a vertical direction.

3. The method of claim 1, wherein performing the optical proximity correction on the second target pattern includes:
generating first mask control points on each of the curved edges; and
generating second mask control points on each of the second straight edges.

4. The method of claim 3, wherein a density of the first mask control points is different from a density of the second mask control points.

5. The method of claim 4, wherein the density of the first mask control points is greater than the density of the second mask control points.

6. The method of claim 3, wherein a first spacing between two adjacent ones of the first mask control points is different from a second spacing between two adjacent ones of the second mask control points.

7. The method of claim 6, wherein the first spacing is smaller than the second spacing.

8. The method of claim 1, wherein the corner portions include a first corner portion,
wherein the first corner portion has a step shape including an outer corner and an inner corner adjacent to the outer corner.

9. The method of claim 8, wherein the curved edges of the second target pattern include a first curved edge,
wherein generating the second target pattern includes changing the first corner portion of the first target pattern to a curve protruding outwardly from the outer corner and depressed inwardly from the inner corner, to generate the first curved edge.

10. A method for fabricating a mask, the method comprising:
generating a target pattern including straight edges and curved edges;
performing optical proximity correction on the target pattern to generating a mask pattern; and
fabricating the mask using the mask pattern,
wherein performing the optical proximity correction on the target pattern includes:
generating first mask control points on each of the straight edges of the target pattern; and
generating second mask control points on each of the curved edges of the target pattern, and
wherein a density of the first mask control points is different from a density of the second mask control points.

11. The method of claim 10, wherein the density of the second mask control points is greater than the density of the first mask control points.

12. The method of claim 11, wherein a first spacing between two adjacent ones of the first mask control points is different from a second spacing between two adjacent ones of the second mask control points.

13. The method of claim 12, wherein the second spacing is smaller than the first spacing.

14. The method of claim 10, wherein the straight edges include a first horizontal edge and a second horizontal edge extending in the horizontal direction and positioned at different vertical levels,
wherein the curved edges include a first curved edge, and
wherein the first horizontal edge, the first curved edge and the second horizontal edge are sequentially connected to each other.

15. The method of claim 14, wherein the first curved edge has a first portion connected to the first horizontal edge and curved in a first direction, and a second portion connected to the second horizontal edge and curved in a second direction, and
wherein the second direction is different from the first direction.

16. The method of claim 10, wherein the straight edges include a first horizontal edge extending in a horizontal direction and a first vertical edge extending in a vertical direction,
wherein the curved edges include a first curved edge, and
wherein the first horizontal edge, the first curved edge and the first vertical edge are sequentially connected to each other.

17. The method of claim 10, wherein the target pattern has a line shape extending in an elongate manner in a horizontal direction and having a first width in a vertical direction.

18. The method of claim 10, wherein the target pattern includes a portion having a first width in a vertical direction and a second portion having a second width in the vertical direction smaller than the first width, wherein the target pattern has a line shape extending in an elongate manner in a horizontal direction.

19. A method for manufacturing a semiconductor device, the method comprising:
fabricating a mask; and
performing a photolithographic process on a substrate using the mask,
wherein fabricating the mask includes:
receiving a first target pattern including a first straight edge and a second straight edge extending in a horizontal direction, and a step edge connecting the first straight edge and the second straight edge to each other;
generating a second target pattern from the first target pattern, including changing the step edge of the first target pattern to a curve to generate a curved edge;
performing optical proximity correction on the second target pattern to generate a mask pattern; and
fabricating the mask using the mask pattern.

20. The method of claim 19, wherein the second target pattern further includes:
a third straight edge corresponding to the first straight edge of the first target pattern;
a fourth straight edge corresponding to the second straight edge of the first target pattern; and
the curved edge connecting the third straight edge and the fourth straight edge to each other,
wherein performing the optical proximity correction on the second target pattern includes:
generating first mask control points on the curved edge; and
generating second mask control points on each of the third straight edge and the fourth straight edge.

21-22. (canceled)
